(19) United States
(12) Patent Application Publication
(10) Pub. No.: US 2018/0347603 A1
(43) Pub. Date: Dec. 6, 2018

(54) Toolless Mounting System For An Electronics Rack Component

(71) Applicant: Middle Atlantic Products, Inc., Fairfield, NJ (US)

(72) Inventors: Nico Corbo, Blairstown, NJ (US); John Franetovich, Glenwood, NJ (US); Eric Christ, Haskell, NJ (US)

(21) Appl. No.: 15/988,824

(22) Filed: May 24, 2018

Related U.S. Application Data
(60) Provisional application No. 62/513,679, filed on Jun. 1, 2017.

(51) Int. Cl. F16B 2/24; F16M 13/02; H05K 7/14

(52) U.S. Cl. CPC F16B 2/243; H05K 7/1401; F16M 13/022

(57) ABSTRACT

A spring locking assembly for removably attaching a component to a framing member of an electronics rack without the need for tools. The spring locking mount includes an attachment bracket with first and second bracket legs formed integral with one another and an angle relative to one another. A spring clip includes a mounting flange that is attached to a top surface of the first bracket leg near a hole, the spring clip has a protrusion that is formed near an end of the spring clip spaced apart from the mounting flange. The protrusion extends through the hold in the first leg past its bottom surface. The spring clip biases the protrusion into the hole. At least one protrusion extends outward from a back surface of the second bracket leg.

### RELATED APPLICATION

This application is related to and claims priority from U.S. Provisional Patent Application 62/513,679, filed Jun. 1, 2017, the disclosure of which is incorporated herein by reference in its entirety.

### FIELD OF THE INVENTION

A system for mounting shelves and similar components to an electronics rack and, more particularly to a toolless mount that permits easy attachment of such components, eliminating the need for rack screws.

### BACKGROUND

Most electronics racks, such as computer and A/V racks, are configured to be assembled through the use of screws and bolts. This type of assembly is used not just for the main frames, but also for the component shelves. Thus, in order to modify the shelving arrangement, a service technician has to unscrew the shelves to move them to a new location.

A toolless mounting system was created by Middle Atlantic Products called the Lever Lock® locking mechanism which removably secures shelves, brackets and other components to racks using a lock that can be disengaged with a user's fingers. The Lever Lock® locking mechanism is described in U.S. Pat. No. 9,131,622, the disclosure of which is incorporated herein by reference in its entirety.

While the Lever Lock® locking mechanism provide an improvement over conventional mounting systems, a need continues to exist for other forms of toolless mounting systems.

### SUMMARY OF THE INVENTION

A spring locking assembly is disclosed for removably attaching a component to a framing member of an electronics rack without the need for tools. The framing member includes first and second frame legs formed integral with one another and an angle relative to one another. The spring locking mount includes an attachment bracket with first and second bracket legs formed integral with one another and at an angle relative to one another. The first bracket leg has a plurality of spaced apart holes formed through it. A spring clip includes a mounting flange that is attached to a top surface of the first bracket leg near one of the holes and has a protrusion that is formed near an end of the spring clip spaced apart from where the mounting flange attaches to the first leg. The protrusion is located such that the protrusion extends through one of the holes in first leg and past a bottom surface of the first leg. The spring clip biases the protrusion into the hole. At least one protrusion extends outward from a back surface of the second bracket leg.

In an embodiment there are at least two spring clips, each spring clip including a mounting flange that is attached to a top surface of the first bracket leg near one of the holes and with each spring clip having a protrusion that is formed near an end of the spring clip spaced apart from where the mounting flange attaches to the first leg. Each protrusion is located such that the protrusion extends through one of the holes in first leg and past a bottom surface of the first leg. Each spring clip configured to bias the protrusion into the hole.

In an embodiment the spring clip may have a second end that is on the opposite side of and spaced apart from the mounting flange from the first end, and with a second protrusion that is formed near the second end. The second protrusion is located such that the second protrusion extends through a second hole of the plurality of holes in first leg and past the bottom surface of the first leg. The spring clip is configured to bias the second protrusion into the second hole.

Preferably the angle between the first and second bracket legs is between about 60 degrees to about 120 degrees. In an embodiment, the angle between the first and second bracket legs is between about 75 degrees to about 105 degrees. In an embodiment, the angle between the first and second bracket legs is more preferably between about 80 degrees to about 100 degrees.

In an embodiment the angle between the first and second bracket legs is about 90 degrees.

In an embodiment, the attachment bracket has an angle between the first and second bracket legs that is configured such that the first and second bracket legs nest within the first and second frame legs.

Preferably the spring clip is attached to the first leg of the bracket with at least one of a screw, rivet, welding or adhesive. Preferably the spring clip is made from spring steel. Preferably there are at least two spring clips mounted to the bracket leg. More preferably the two spring clips are attached to or integral with one another.

In an embodiment, the protrusion on the spring clip has a depth that is sufficiently deep to extend below the bottom of the first bracket leg and into a mounting hole in the first frame leg when the spring locking mount is attached to the framing member.

Preferably the second bracket leg has a plurality of spaced apart holes formed through it and the protrusion on the second bracket leg is a pin that extends through one of the holes. Preferably there is a second pin on the second bracket leg that is spaced apart from the first pin and extends through another of the holes in the second bracket leg. In an embodiment, the protrusion on the second bracket leg is located so as to align with and extend into a corresponding mounting hole in the second frame leg.

In an embodiment, the spring locking assembly is removably attached to the framing member. The component includes a flange attached to the second bracket leg and the protrusion on the first bracket leg extends into a hole in the first frame leg thereby securing the flange of the component to the framing member.

In an embodiment the spring locking assembly is disclosed that includes at least two spring clips and at least two protrusions extending outward from a back surface of the second bracket leg.

A method of removably attaching a component to a framing member of an electronics rack without the need for tools is disclosed. The method involves providing a framing member having first and second frame legs formed integral with one another and defining an angle therebetween, providing the spring locking assembly according to any of the embodiments and providing a component for mounting to the framing member. The attachment bracket of the spring locking assembly is placed against the framing member such that the first bracket leg is proximate to the first frame leg and the second bracket leg is proximate to the second frame leg. The protrusions on the second bracket leg are inserted into holes on the second frame leg. The protrusions on the spring clip are biased into the holes the first bracket leg and holes in the first frame leg. Thus, the combination of the protrusions on the second bracket leg extending into holes on the second frame leg and the protrusions on the spring clip protruding into the holes the first bracket leg and holes in the first frame leg removably secure the component to the framing member.

In an embodiment of the method, the protrusion on the second bracket leg is a pin extending outward from a back surface of the second bracket leg, and the component is integrally attached to the second bracket leg.

In an embodiment of the method the protrusion on the second bracket leg is a pin extending outward from a back surface of the second bracket leg and the component has a flange with holes aligned with the holes in the second frame leg. The flange is located between the second bracket leg and the second frame leg and the pin on the second bracket leg extends through the holes in the second bracket leg and the second frame leg.

The foregoing and other features of the invention and advantages of the present invention will become more apparent in light of the following detailed description of the preferred embodiments, as illustrated in the accompanying figures. As will be realized, the invention is capable of modifications in various respects, all without departing from the invention. Accordingly, the drawings and the description are to be regarded as illustrative in nature, and not as restrictive.

### BRIEF DESCRIPTION OF THE DRAWINGS

For the purpose of illustrating the invention, the drawings show a form of the invention which is presently preferred. However, it should be understood that this invention is not limited to the precise arrangements and instrumentalities shown in the drawings.

FIG. 1 is a side view of an embodiment of a spring locking mount for an electronics rack component.

FIG. 2 is a cross-sectional view of the spring locking mount of FIG. 1, taken along lines 2-2 in FIG. 3.

FIG. 3 is a cross-sectional view of the spring locking mount of FIG. 1, taken along lines 3-3 in FIG. 1.

FIG. 4 is a cross-sectional view of the spring locking mount of FIG. 1, taken along lines 4-4 in FIG. 1.

FIG. 5 is a cross-sectional view of an alternate embodiment of the spring locking mount with an attachment bracket that is separately attached to an electronics rack component.

FIG. 6 is a side view of an embodiment of a spring locking mount for an electronics rack component.

FIG. 7 is a cross-sectional view of the spring locking mount of FIG. 6

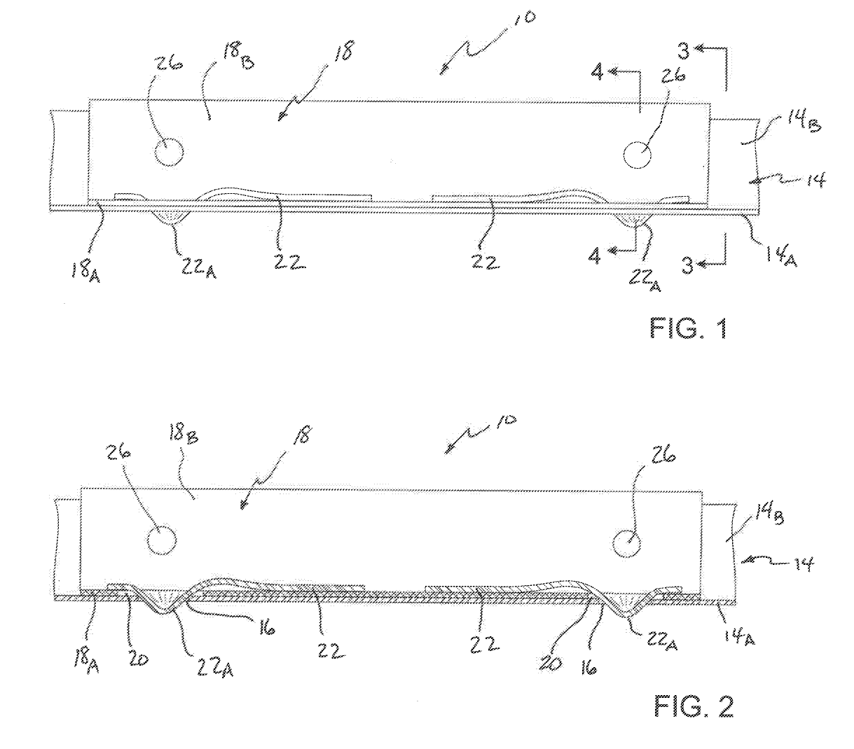

### DESCRIPTION OF THE PREFERRED EMBODIMENTS

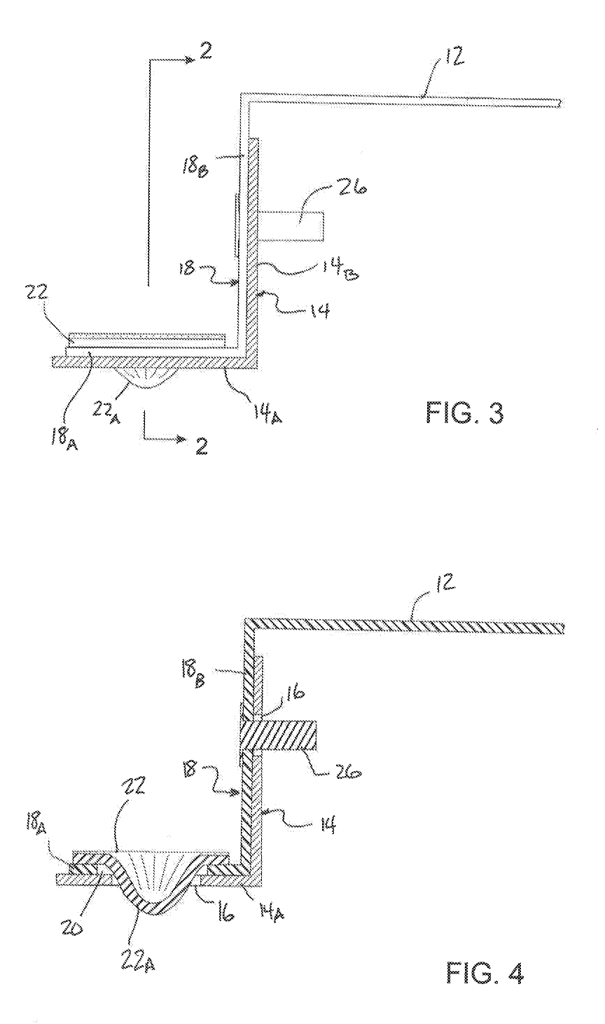

The present invention relates to a locking system for securing components, such as brackets and panels to an electronics rack frame without the need for tools. Referring now to the figures, an embodiment of a spring locking assembly or mount 10 is illustrated. The spring locking assembly 10 is attached to or formed integral with a component of an electronics rack, such as a shelf 12, mounting plate, bracket, or any mountable accessory or component that is typically attached to a frame in an electronics rack with screws. A conventional electronics rack, such as an EIA-310, includes support posts or beams 14 that include metal angles with first and second legs 14_{A}, 14_{B} at an angle to one another, typically 90 degrees, as such as shown in FIG. 3. The supports 14 include a plurality of mounting holes 16 that are formed in each leg are defined locations. Conventional vertical hole spacing in the supports is defined as a repeating pattern of holes within one rack unit of 1.75″ (1 RU). The hole pattern generally comprises a ½″ spacing, followed by a ⅝″ spacing, then another ⅝″ spacing. That pattern repeats along at least most of the vertical length of the support.

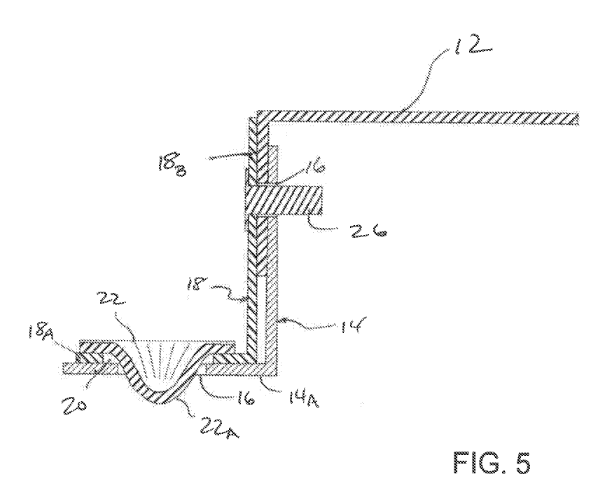

The spring locking assembly 10 includes an attachment bracket 18 with first and second legs 18_{A}, 18_{B} that are formed at an angle to one another, which angle is substantially the same as the angle of the support 14 such that legs 18_{A}, 18_{B} nest within legs 14_{A}, 14_{B}. The illustrated embodiment shows the respective angles between the sets of legs 18_{A}, 18_{B} and legs 14_{A}, 14_{B} are each about 90 degrees. However, as will be apparent, the present invention is applicable to brackets that are at various angles, for example preferably between about 60 degrees to about 120 degrees; between about 75 degrees to about 105 degrees; or most preferably between about 80 degrees to about 100 degrees. As shown, the second leg 18_{B} of the attachment bracket 18 may be formed integral with the electronics component 12. However, it is also contemplated that the second leg 18_{B} of the attachment bracket 18 could be separately attached to the electronics component 12. See, FIG. 5. Each of the first and second legs 18_{A}, 18_{B} of the attachment bracket 18 includes at least one, and more preferably multiple attachment holes 20 in the leg at spaced apart locations that correspond to holes 16 formed in the legs 14_{A}, 14_{B} of the support 14.

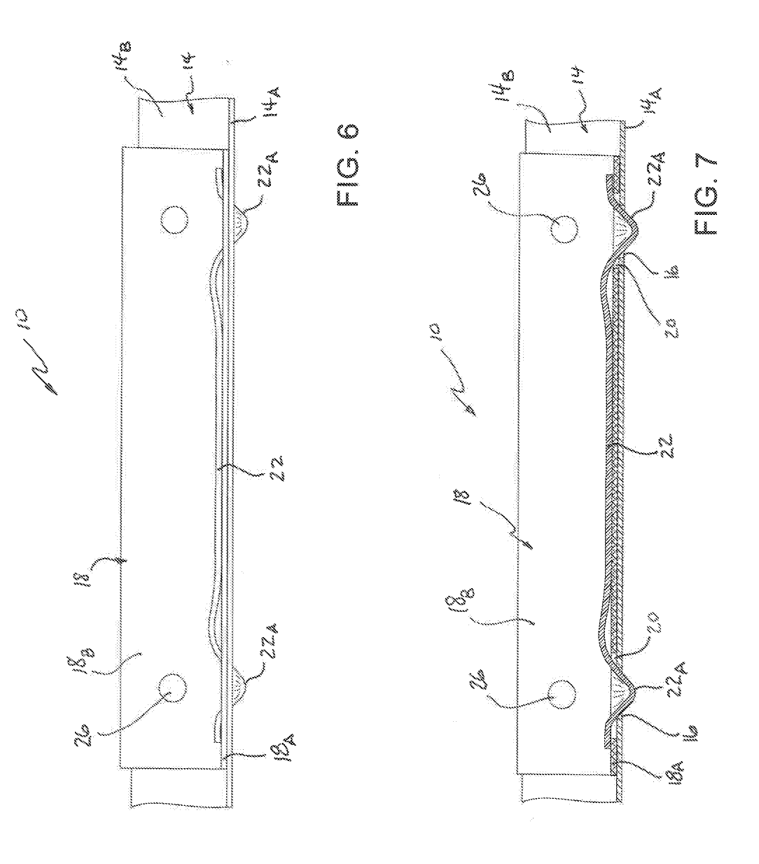

At least one spring clip 22 is affixed to the top surface of the first leg 18_{A} of the attachment bracket 18, such as by screws, rivets, welding or adhesive. Preferably there are at least two spring clips 22 on each attachment bracket 18 (or one spring assembly with two or more spring clips 22 attached to one another—See. FIG. 6). The spring clip 22 includes a protrusion 22_{A} that is formed near an opposite end of the spring clip 22 from where it attaches to the first leg 18_{A} of the attachment bracket 18. The protrusion 22_{A} is located relative to the attachment bracket 18 such that the protrusion extends through the attachment hole 20 in first leg 18_{A} as shown in the figures. The spring clip 22 is formed such that the protrusion 22_{A} is resiliently biased into the hole 20. The protrusion 22_{A} has a depth that is sufficiently deep (i.e., extends a distance below the bottom of the leg 18_{A}) so that the protrusion 22_{A} extends into the mounting hole 16 formed in leg 14_{A} of the support 14 when the attachment bracket 18 is seated on the support 14. Although the illustrated embodiment shows two separate spring clips 22, it should be readily apparent that the two clips could be integral with one another. An embodiment of this is shown in FIGS. 6 and 7. The spring clip 22 is preferably made from steel material with a sufficient resiliency, such as spring steel or other suitable spring material.

At least one pin 26 is attached to the second leg 18_{B} of the attachment bracket 18 and extends away from the side of attachment bracket 18 where the spring clip 22 is attached (i.e., it extends toward support 14). The pin 26 is located so as to align with and extend into a corresponding mounting hole 16 in the second leg 14_{B}. There are preferably at least two pins 26 at spaced apart locations on the second leg 18_{B} of the attachment bracket 18 that correspond with mounting holes in the support 14. Although pins 26 are shown in the figures, it should be apparent that the pins could be replaced by bolts or could be protrusions extending out of the second leg 18_{B}.

As should be apparent from the figures, when the pins 26 are inserted into the mounting holes 16 on a support 14, the protrusions 22_{A} will first deflect when they contact the edge of the first leg 14_{A} of the support 14 and then snap into the holes 16 in the first leg 14_{A}, thus locking the attachment bracket 18 to the support 14 without the need for tools.

FIG. 5 illustrates a cross sectional view similar to FIG. 4 depicting the invention when used with an attachment bracket 18 that is separate from an electronics component 12. In this embodiment, the pin 26 extends through an existing hole in a flange of the electronics component 12 and then into the mounting hole in the support

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and similar referents in the context of describing the invention (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. The term “connected” is to be construed as partly or wholly contained within, attached to, or joined together, even if there is something intervening.

The recitation of ranges of values herein are merely intended to serve as a shorthand method of referring individually to each separate value falling within the range, unless otherwise indicated herein, and each separate value is incorporated into the specification as if it were individually recited herein.

All methods described herein can be performed in any suitable order unless otherwise indicated herein or otherwise clearly contradicted by context. The use of any and all examples, or exemplary language (e.g, “such as”) provided herein, is intended merely to better illuminate embodiments of the invention and does not impose a limitation on the scope of the invention unless otherwise claimed. The various embodiments and elements can be interchanged or combined in any suitable manner as necessary.

No language in the specification should be construed as indicating any non-claimed element as essential to the practice of the invention.

It will be apparent to those skilled in the art that various modifications and variations can be made to the present invention without departing from the spirit and scope of the invention. There is no intention to limit the invention to the specific form or forms disclosed, but on the contrary, the intention is to cover all modifications, alternative constructions, and equivalents falling within the spirit and scope of the invention, as defined in the appended claims. Thus, it is intended that the present invention cover the modifications and variations of this invention provided they come within the scope of the appended claims and their equivalents.

1. A spring locking assembly for removably attaching a component to a framing member of an electronics rack without the need for tools, the framing member including first and second frame legs formed integral with one another and an angle relative to one another, the spring locking mount comprising:
an attachment bracket with first and second bracket legs formed integral with one another and an angle relative to one another, the first bracket leg having a plurality of spaced apart holes formed through it;
a spring clip, the spring clip including a mounting flange that is attached to a top surface of the first bracket leg near one of the holes, the spring clip having a protrusion that is formed near an end of the spring clip spaced apart from where the mounting flange attaches to the first leg, the protrusion located such that the protrusion extends through one of the holes in first leg and past a bottom surface of the first leg, the spring clip biasing the protrusion into the hole; and
at least one protrusion extending outward from a back surface of the second bracket leg.

2. The spring locking assembly of claim 1, wherein there are at least two spring clips, each spring clip including a mounting flange that is attached to a top surface of the first bracket leg near one of the holes, each spring clip having a protrusion that is formed near an end of the spring clip spaced apart from where the mounting flange attaches to the first leg, each protrusion located such that the protrusion extends through one of the holes in first leg and past a bottom surface of the first leg, the spring clip configured to bias the protrusion into the hole.

3. The spring locking assembly of claim 1, wherein the spring clip has a second end that is on the opposite side of and spaced apart from the mounting flange from the first end, the spring clip having a second protrusion that is formed near the second end, the second protrusion located such that the second protrusion extends through a second hole of the plurality of holes in first leg and past the bottom surface of the first leg, the spring clip configured to bias the second protrusion into the second hole.

4. The spring locking assembly of claim 1, wherein the angle between the first and second bracket legs is between about 60 degrees to about 120 degrees.

5. The spring locking assembly of claim 4, wherein the angle between the first and second bracket legs is between about 75 degrees to about 105 degrees.

6. The spring locking assembly of claim 4, wherein the angle between the first and second bracket legs is between about 80 degrees to about 100 degrees.

7. The spring locking assembly of claim 1, wherein the angle between the first and second bracket legs is about 90 degrees.

8. The spring locking assembly of claim 1, wherein the attachment bracket has an angle between the first and second bracket legs that is configured such that the first and second bracket legs nest within the first and second frame legs.

9. The spring locking assembly of claim 1, wherein the spring clip is attached to the first leg of the bracket with at least one of a screw, rivet, welding or adhesive.

10. The spring locking assembly of claim 1, wherein there are at least two spring clips mounted to the bracket leg.

11. The spring locking assembly of claim 10, wherein the at least two spring clips are attached to or integral with one another.

12. The spring locking assembly of claim 11, wherein the spring clip is made from spring steel.

13. The spring locking assembly of claim 1, wherein the protrusion on the spring clip has a depth that is sufficiently deep to extend below the bottom of the first bracket leg and into a mounting hole in the first frame leg when the spring locking mount is attached to the framing member.

14. The spring locking assembly of claim 1, wherein the second bracket leg has a plurality of spaced apart holes formed through it and wherein the protrusion on the second bracket leg is a pin that extends through one of the holes.

15. The spring locking assembly of claim 14, wherein there is a second pin on the second bracket leg that is spaced apart from the first pin and extends through another of the holes in the second bracket leg.

16. The spring locking assembly of claim 1, wherein protrusion on the second bracket leg is located so as to align with and extend into a corresponding mounting hole in the second frame leg.

17. The spring locking assembly of claim 1, wherein the spring locking assembly is removably attached to the framing member, wherein the component includes a flange attached to the second bracket leg and the protrusion on the first bracket leg extends into a hole in the first frame leg thereby securing the flange of the component to the framing member.

18. A spring locking assembly for removably attaching a component to a framing member of an electronics rack without the need for tools, the framing member including first and second frame legs formed integral with one another and an angle relative to one another, the spring locking mount comprising:
an attachment bracket with first and second bracket legs formed integral with one another and an angle relative to one another, the first bracket leg having a plurality of spaced apart holes formed through it;
at least two spring clips, each spring clip including a mounting flange that is attached to a top surface of the first bracket leg near one of the holes, each spring clip having a protrusion that is formed near an end of the spring clip spaced apart from where the mounting flange attaches to the first leg, each protrusion located such that the protrusion extends through one of the holes in first leg and past a bottom surface of the first leg, the spring clip configured to bias the protrusion into the hole; and
at least two protrusions extending outward from a back surface of the second bracket leg.

19. A method of removably attaching a component to a framing member of an electronics rack without the need for tools comprising the steps of:
providing a framing member having first and second frame legs formed integral with one another and defining an angle therebetween;
providing the spring locking assembly of claim 1;
providing a component for mounting to the framing member;
placing the attachment bracket of the spring locking assembly against the framing member such that the first bracket leg is proximate to the first frame leg and the second bracket leg is proximate to the second frame leg;
causing the protrusions on the second bracket leg to extend into holes on the second frame leg; and
causing the protrusions on the spring clip be biased into the holes the first bracket leg and holes in the first frame leg;
whereby the combination of the protrusions on the second bracket leg extending into holes on the second frame leg and the protrusions on the spring clip protruding into the holes the first bracket leg and holes in the first frame leg removably secures the component to the framing member.

20. The method of claim 20, wherein the protrusion on the second bracket leg is a pin extending outward from a back surface of the second bracket leg, and wherein the component is integrally attached to the second bracket leg.

21. The method of claim 20, wherein the protrusion on the second bracket leg is a pin extending outward from a back surface of the second bracket leg, wherein the component has a flange with holes aligned with the holes in the second frame leg, the flange being located between the second bracket leg and the second frame leg and wherein the pin on the second bracket leg extends through the holes in the second bracket leg and the second frame leg.
